(19) United States
(12) Patent Application Publication
(10) Pub. No.: US 2009/0159313 A1
(43) Pub. Date: Jun. 25, 2009

(54) CURABLE EPOXY RESIN COMPOSITION AND LAMINATES MADE THEREFROM

(76) Inventors: Ludovic Valette, Shanghai (CN); Tomoyuki Aoyama, Tokyo (JP)

Correspondence Address: The Dow Chemical Company, Intellectual Property Section, P.O. Box 1967, Midland, MI, 48641-1967, US

(21) Appl. No.: 12/097,647

(22) PCT Filed: Dec. 20, 2006
(86) PCT No.: PCT/US2006/048578

§ 371 Date: Nov. 7, 2008

Related U.S. Application Data
(60) Provisional application No. 60/753,028, filed on Dec. 22, 2005.

(51) Int. Cl. H05K 1/00; C08L 63/00; B32B 27/38; B05D 3/02; D03D 25/00; B32B 15/092

(52) U.S. Cl. 174/250; 525/523; 428/413; 427/386; 442/181; 428/418

(57) ABSTRACT

A curable halogen-containing epoxy resin composition comprising: (a) at least one epoxy resin; (b) at least one hardener; wherein the hardener is a compound containing a phenolic hydroxyl functionality or a compound capable of generating a phenolic hydroxyl functionality upon heating; (c) a catalytic amount of a nitrogen-containing catalyst; (d) a non-nitrogen containing catalyst adjuvant compound capable of reducing the concentration of the nitrogen-containing catalyst; wherein at least one of the above components (a)-(d) is halogenated or wherein the resin composition includes (e) a halogenated flame retardant compound. The stroke cure gel time of the resin composition is maintained from 90 seconds to 600 seconds when measured at 1700C; and the resultant cured product formed by curing the curable epoxy resin composition contains well-balanced properties. The composition may be used to obtain a prepreg or a metal-coated foil, or a laminate by laminating the above prepreg and/or the above metal-coated foil. The laminate shows a combination of superior glass transition temperature, decomposition temperature, time to delamination at 288° C., adhesion to copper foil, and excellent flame retardancy.

The present invention relates to thermosetting epoxy resin compositions containing a certain catalyst system, to processes utilizing these compositions and to articles made from these compositions. More specifically, the present invention relates to an epoxy resin composition including a nitrogen-containing catalyst and a catalyst adjuvant comprising a compound containing a carboxylic acid or an anhydride group. The catalyst adjuvant is a compound capable of reducing the concentration of the nitrogen-containing catalyst in the composition. Articles prepared from the resin compositions of the present invention exhibit enhanced thermal properties and other well-balanced properties. The resin compositions of the present invention may be used for any purpose, but are particularly suited to be utilized in the manufacture of laminates, more specifically, electrical laminates for printed circuit boards. The electrical laminates prepared from the composition of the present invention have superior thermal stability and excellent balance of properties.

Articles prepared from resin compositions which have improved resistance to elevated temperatures are desirable for many applications. In particular these articles, having improved elevated temperature resistance, are desirable for printed circuit board (PCB) applications due to industry trends which include higher circuit densities, increased board thickness, lead free solders, and higher temperature use environments.

Articles such as laminates, and particularly structural and electrical copper clad laminates, are generally manufactured by pressing, under elevated temperatures and pressures, various layers of partially cured prepregs and optionally copper sheeting. Prepregs are generally manufactured by impregnating a curable thermosettable epoxy resin composition into a porous substrate, such as a glass fiber mat, followed by processing at elevated temperatures to promote a partial cure of the epoxy resin in the mat to a “B-stage.” Complete cure of the epoxy resin impregnated in the glass fiber mat typically occurs during the lamination step when the prepreg layers are pressed under high pressure and elevated temperatures for a time sufficient to allow for complete cure of the resin when preparing a laminate.

While epoxy resin compositions are known to impart enhanced thermal properties for the manufacture of prepregs and laminates, such epoxy resin compositions are typically more difficult to process, more expensive to formulate, and may suffer from inferior performance capabilities for complex printed circuit board circuitry and for higher fabrication and usage temperatures.

In light of the above, there is a need in the art for epoxy resin compositions for preparing articles having improved thermal properties and for processes to produce such articles. There is also a need in the art for inexpensive resin compositions for achieving enhanced thermal properties and for articles, especially prepregs and laminates, having enhanced thermal properties.

In particular, there continues to be a need for higher thermally resistant laminates used as substrates for PCBs in order to manage lead-free soldering temperatures and higher in-use thermal exposure requirements. Standard FR-4 laminates which are normally used in PCBs are made of brominated epoxy resins cured with dicyandiamide. These standard FR-4 laminates have low thermally stability, that is low degradation temperature (Td) and short time to delamination at 288° C. (T288).

Improved thermal stability can be achieved when a phenolic or an anhydride hardener is used instead of dicyandiamide in a varnish formulation for making laminates. However, such varnishes have narrow processing window. Often the resulting laminate from such varnish has a lower glass transition temperature (Tg), and a lower adhesion to copper foil. The laminates are also more brittle.

High internal weight carboxylic anhydride are also known to be used as curing agents. The use of high molecular weight carboxylic anhydride as curing agents leads to poor prepreg cosmetics due to the high melt viscosity of the prepreg powder. The prepreg is usually more brittle, resulting in the formation of dust when such prepreg is cut and trimmed. The formation of dust is referred to in the art as a “mushroom effect”.

It is typical in the known art that the improvement of one property of an epoxy composition or a laminate made therefrom is usually achieved at the expense of another property, and not all properties thereof can be improved at the same time. Some known process use expensive specialty resins and hardeners in an attempt to achieve a resin with will-balanced properties.

The use of non-brominated flame retardant epoxy resins can, for example, provide laminates with a high thermal stability. However, the use of non-brominated flame retardant epoxy resins is limited because of their higher price when compared to standard FR-4 laminate resins. Also, the use of non-brominated epoxy resins leads to a poor balance of properties of the resulting laminates. For example, a laminate made from a non-brominated epoxy resin may exhibit a lower Tg, a higher brittleness, and a higher sensitivity to moisture.

In spite of recent improvements made to resin compositions and processes for making electrical laminates, none of the known prior art references disclose a resin composition useful for making a laminate with a good balance of laminate properties and thermal stability, such as high Tg, good toughness, and good adhesion to copper foil.

It would be desirable to provide a curable epoxy resin composition with excellent well-balanced properties for use as a material for making a laminate such that the laminate has excellent well-balanced laminate properties. It would also be desirable to achieve a laminate having high thermal stability with high Tg, good toughness, and good adhesion to copper foil without the use of expensive specialty resins or hardeners.

One aspect of the present invention is directed to a curable halogen-containing epoxy resin composition comprising: (a) at least one epoxy resin; (b) at least one hardener; wherein the hardener is a compound containing a phenolic hydroxyl functionality or a compound capable of generating a phenolic hydroxyl functionality upon heating; (c) a catalytic amount of a nitrogen-containing catalyst; and (d) a non-nitrogen containing catalyst adjuvant compound capable of reducing the concentration of the nitrogen-containing catalyst; wherein at least one or more of the above components (a)-(d) is halogenated; or if none of the above components are halogenated wherein the resin composition includes (e) a halogenated or halogen-containing flame retardant compound; characterized in that the stroke cure gel time of the resin composition is maintained from 90 seconds to 600 seconds when measured at 170° C.; and such that a resultant cured product formed by curing the curable epoxy resin composition contains the following well-balanced properties: (1) a glass transition temperature (Tg) of greater than 130° C.; (2) a decomposition temperature (Td) of greater than 320° C.; (3) a time to delamination at 288° C. (T288) of greater than 1 minute; (4) an adhesion to copper of greater than 10 N/cm; and (5) a UL94 flame retardancy ranking of at least V-1.

In one embodiment, the non-nitrogen containing catalyst adjuvant compound capable of reducing the concentration of nitrogen-containing catalyst is a compound that contains a carboxylic acid or an anhydride group.

Another aspect of the present invention is directed to the use of the above composition to obtain a prepreg or a metal-coated foil; and to a laminate obtained by laminating the above prepreg and/or the above metal-coated foil. The resultant laminate shows a combination of well-balanced properties including superior glass transition temperature, decomposition temperature, time to delamination at 288° C., and adhesion to copper foil.

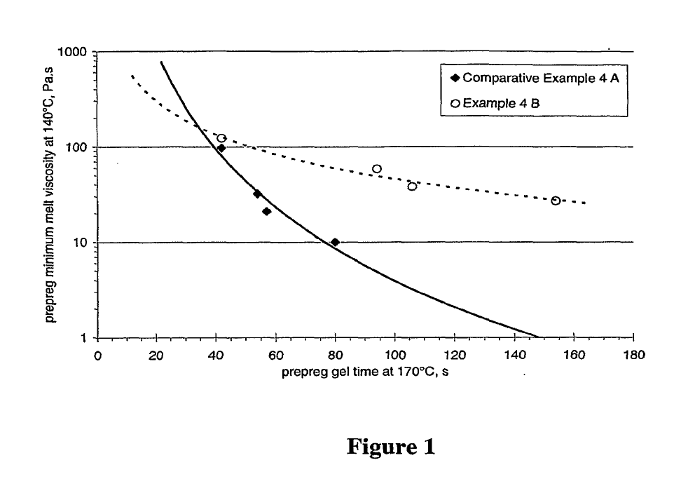

FIG. 1 is a graphical illustration showing the variation of prepreg minimum melt viscosity as a function of prepreg gel time (processing window) comparing two different prepregs made from two resin compositions of the present invention with a prepreg made from a comparative resin composition.

In general, the curable halogen-containing epoxy resin composition of the present invention includes the following components: (a) at least one epoxy resin; (b) at least one hardener; wherein the hardener is a compound containing at least one phenolic hydroxyl functionality or a hardener compound capable of generating at least one phenolic hydroxyl functionality; (c) a catalytic amount of at least one nitrogen-containing catalyst for example wherein the catalyst is present in a concentration of less than 10 percent by weight on solids; and (d) a non-nitrogen containing catalytic adjuvant compound in a concentration sufficient to reduce the concentration of nitrogen-containing catalyst to a smaller catalytic amount while maintaining the catalytic activity of the nitrogen-containing catalyst and maintaining varnish gel time. In the above halogen-containing epoxy resin composition at least one or more of components (a), (b), (c), or (d) may be a halogen-containing compound in order for the final resin composition to be halogen-containing and have flame retardant properties. If none of the components (a)-(d) are halogen-containing, then in order for the final resin composition to be halogen-containing an additional component such as (e) a halogenated flame retardant compound may optionally be added to the resin composition.

The curable epoxy resin composition of the present invention, after curing, provides a cured product, for example a laminate, with excellent balance of properties including, for example, glass transition temperature (Tg), decomposition temperature (Td), time to delamination at 288° C. (T288), adhesion to copper foil (copper peel strength), and flame retardancy (flame retardancy ranking at least UL94 V-1, preferably UL94 V-0).

The present invention provides an improved epoxy resin system that can be used for making electrical laminates, including prepregs and laminates for PCB. The curable epoxy resin composition of the present invention can give a cured product having excellent balance of the following properties, for example: Tg, Td, T288, adhesion and flame retardancy while not detrimentally effecting other properties such as toughness, moisture resistance, dielectric constant (Dk) and dielectric loss factor (Df), thermomechanical properties (coefficient of thermal expansion, modulus), and processing window; and cost. The composition provides prepregs and laminates with high thermal stability and excellent overall balance of properties, that is, high Tg, high adhesion and good toughness.

Generally, the present invention includes the use of a specific compound, herein referred to as a “catalyst adjuvant”, capable of reducing the concentration of the nitrogen-containing catalyst from catalytic quantity that would normally be used in an epoxy-containing varnish containing at least a phenolic hardener, to a smaller catalytic quantity while maintaining similar varnish gel time. Such a system leads to improved prepregs after partial cross-linking and to improved laminates after extensive cross-linking. These laminates display a high thermal stability and an excellent overall balance of other properties, for example high Tg, high adhesion, good toughness. It has been found that there is an unexpected relationship between the thermal stability and the concentration of nitrogen-containing catalyst. The lower the concentration of nitrogen-containing catalyst is, the higher the thermal stability. However, the addition of a small amount of nitrogen-containing catalyst may be suitable to conveniently adjust the varnish reactivity and to maintain excellent laminate properties such as high Tg. When the composition contains a cure inhibitor, such as boric acid, it is particularly useful to maintain the presence of a portion of imidazole catalyst since boric acid forms complexes with imidazoles which act as latent catalyst for the composition.

The properties of the cured product that are well-balanced in accordance with the present invention include: a glass transition temperature (Tg) of greater than 130° C., preferably a Tg of greater than 140° C., more preferably a Tg of greater than 150° C., and even more preferably a Tg of greater than 170° C.; a decomposition temperature (Td) of greater than 320° C., preferably a Td of greater than 330° C., more preferably a Td of greater than 340° C., and even more preferably a Td of greater than 350° C.; a time to delamination at 288° C. (T288) of greater than 1 minute, preferably a T288 of greater than 5 minutes, more preferably a T288 of greater than 10 minutes, and even more preferably a T288 of greater than 15 minutes; an adhesion to copper foil (conventional 1 oz copper foil) such as a peel strength of greater than 10 N/cm, preferably a peel strength of greater than 12 N/cm, and more preferably a peel strength of greater than 16 N/cm; and a flame retardancy in terms of a UL94 ranking of at least V-1 and preferably V-0.

The curable halogen-containing epoxy resin composition of the present invention includes at least one epoxy resin component. Epoxy resins are those compounds containing at least one vicinal epoxy group. The epoxy resin may be saturated or unsaturated, aliphatic, cycloaliphatic, aromatic or heterocyclic and may be substituted. The epoxy resin may also be monomeric or polymeric.

Preferably the epoxy resin component is a polyepoxide. Polyepoxide as used herein refers to a compound or mixture of compounds containing more than one epoxy moiety. Polyepoxide as used herein includes partially advanced epoxy resins that is, the reaction of a polyepoxide and a chain extender, wherein the reaction product has, on average, more than one unreacted epoxide unit per molecule. Aliphatic polyepoxides may be prepared from the known reaction of epihalohydrins and polyglycols. Other specific examples of aliphatic epoxides include trimethylpropane epoxide, and diglycidyl-1,2-cyclohexane dicarboxylate. Preferable compounds which can be employed herein include, epoxy resins such as, for example, the glycidyl ethers of polyhydric phenols, that is, compounds having an average of more than one aromatic hydroxyl group per molecule such as, for example, dihydroxy phenols, biphenols, bisphenols, halogenated biphenols, halogenated bisphenols, alkylated biphenols alkylated bisphenols, trisphenols, phenol-aldehyde novolac resins, substituted phenolaldehyde novolac resins, phenol-hydrocarbon resins, substituted phenol-hydrocarbon resins and any combination thereof.

Preferably, the epoxy resins used in the resin composition of the present invention is at least one halogenated or halogen-containing epoxy resin compound. Halogen-containing epoxy resins are compounds containing at least one vicinal epoxy group and at least one halogen. The halogen can be, for example, chlorine or bromine, and is preferably bromine. Examples of halogen-containing epoxy resins useful in the present invention include diglycidyl ether of tetrabromobisphenol A and derivatives thereof. Examples of the epoxy resin useful in the present invention include commercially available resins such as D.E.R.™ 500 series, commercially available from The Dow Chemical Company.

The halogen-containing epoxy resin may be used alone, in combination with one or more other halogen-containing epoxy resins, or in combination with one or more other different non-halogen-containing epoxy resins. The ratio of halogenated epoxy resin to non-halogenated epoxy resin is preferably chosen to provide flame retardancy to the cured resin. The weight amount of halogenated epoxy resin which may be present may vary depending upon the particular chemical structure used (due to the halogen content in the halogenated epoxy resin), as is known in the art. It also depends on the fact that other flame retardants might be present in the composition, including the curing agent and optional additives. The preferred halogenated flame retardants are brominated, preferably diglycidyl ether of tetrabromobisphenol A and derivatives thereof.

In one embodiment, the ratio of halogenated epoxy resin to non-halogenated epoxy resin used in the composition of the present invention is such that the total halogen content in the composition is between 2 percent and 40 percent by weight based on solids (excluding fillers), preferably between 5 percent and 30 percent, and more preferably between 10 percent and 25 percent. In another embodiment, the ratio of halogenated epoxy resin to non-halogenated epoxy resin used in the composition of the present invention is between 100:0 and 2:98 by weight, preferably between 100:0 and 10:90, more preferably between 90:10 and 20:80. In another embodiment, the ratio of halogenated epoxy resin to non-halogenated epoxy resin used in the composition of the present invention is such that the total halogen content in the epoxy resin is between 2 percent and 50 percent by weight based on solids, preferably between 4 percent and 40 percent, and more preferably between 6 percent and 30 percent.

The epoxy resin compounds other than the halogen-containing epoxy resin utilized in the composition of the present invention may be, for example, an epoxy resin or a combination of epoxy resins prepared from an epihalohydrin and a phenol or a phenol type compound, prepared from an epihalohydrin and an amine, prepared from an epihalohydrin and a carboxylic acid, or prepared from the oxidation of unsaturated compounds.

In one embodiment, the epoxy resins utilized in the compositions of the present invention include those resins produced from an epihalohydrin and a phenol or a phenol type compound. The phenol type compound includes compounds having an average of more than one aromatic hydroxyl group per molecule. Examples of phenol type compounds include dihydroxy phenols, biphenols, bisphenols, halogenated biphenols, halogenated bisphenols, hydrogenated bisphenols, alkylated biphenols, alkylated bisphenols, trisphenols, phenol-aldehyde resins, novolac resins (that is the reaction product of phenols and simple aldehydes, preferably formaldehyde), halogenated phenol-aldehyde novolac resins, substituted phenol-aldehyde novolac resins, phenol-hydrocarbon resins, substituted phenol-hydrocarbon resins, phenol-hydroxybenzaldehyde resins, alkylated phenol-hydroxybenzaldehyde resins, hydrocarbon-phenol resins, hydrocarbon-halogenated phenol resins, hydrocarbon-alkylated phenol resins, or combinations thereof.

In another embodiment, the epoxy resins utilized in the compositions of the invention preferably include those resins produced from an epihalohydrin and bisphenols, halogenated bisphenols, hydrogenated bisphenols, novolac resins, and polyalkylene glycols, or combinations thereof. Examples of bisphenol A based epoxy resins useful in the present invention include commercially available resins such as D.E.R™ 300 series and D.E.R.™ 600 series, commercially available from The Dow Chemical Company. Examples of epoxy Novolac resins useful in the present invention include commercially available resins such as D.E.N.™ 400 series, commercially available from The Dow Chemical Company.

In another embodiment, the epoxy resin compounds utilized in the compositions of the invention preferably include those resins produced from an epihalohydrin and resorcinol, catechol, hydroquinone, biphenol, bisphenol A, bisphenol AP (1,1-bis(4-hydroxyphenyl)-1-phenyl ethane), bisphenol F, bisphenol K, tetrabromobisphenol A, phenol-formaldehyde novolac resins, alkyl substituted phenol-formaldehyde resins, phenol-hydroxybenzaldehyde resins, cresol-hydroxybenzaldehyde resins, dicyclopentadiene-phenol resins, dicyclopentadiene-substituted phenol resins, tetramethylbiphenol, tetramethyl-tetrabromobiphenol, tetramethyltribromobiphenol, tetrachlorobisphenol A, or combinations thereof. Preferably, the epoxy resin composition of the present invention contains diglycidyl ether of tetrabromobisphenol A.

The preparation of such compounds is well known in the art. See Kirk-Othmer, Encyclopedia of Chemical Technology, 3rd Ed., Vol. 9, pp 267-289. Examples of epoxy resins and their precursors suitable for use in the compositions of the invention are also described, for example, in U.S. Pat. Nos. 5,137,990 and 6,451,898.

In another embodiment, the epoxy resins utilized in the compositions of the present invention include those resins produced from an epihalohydrin and an amine. Suitable amines include diaminodiphenylmethane, aminophenol, xylene diamine, anilines, or combinations thereof.

In another embodiment, the epoxy resins utilized in the compositions of the present invention include those resins produced from an epihalohydrin and a carboxylic acid. Suitable carboxylic acids include phthalic acid, isophthalic acid, terephthalic acid, tetrahydro- and/or hexahydrophthalic acid, endomethylenetetrahydrophthalic acid, isophthalic acid, methylhexahydrophthalic acid, or combinations thereof.

In another embodiment the epoxy resin refers to an advanced epoxy resin which is the reaction product of one or more epoxy resins components, as described above, with one or more phenol type compounds and/or one or more compounds having an average of more than one aliphatic hydroxyl group per molecule as described above. Alternatively, the epoxy resin may be reacted with a carboxyl substituted hydrocarbon, which is described herein as a compound having a hydrocarbon backbone, preferably a C₁-C₄₀ hydrocarbon backbone, and one or more carboxyl moieties, preferably more than one, and most preferably two. The C₁-C₄₀ hydrocarbon backbone may be a straight- or branched-chain alkane or alkene, optionally containing oxygen. Fatty acids and fatty acid dimers are among the useful carboxylic acid substituted hydrocarbons. Included in the fatty acids are caproic acid, caprylic acid, capric acid, octanoic acid, decanoic acid, lauric acid, myristic acid, palmitic acid, stearic acid, palmitoleic acid, oleic acid, linoleic acid, linolenic acid, erucic acid, pentadecanoic acid, margaric acid, arachidic acid, and dimers thereof.

The epoxy resin, Component (a), of the present invention may be selected from, for example, oligomeric and polymeric diglycidyl ether of bisphenol A, oligomeric and polymeric diglycidyl ether of tetrabromobisphenol A, oligomeric and polymeric diglycidyl ether of bisphenol A and tetrabromobisphenol A, epoxydized phenol Novolac, epoxydized bisphenol A Novolac, oxazolidone-modified epoxy resins and mixtures thereof.

In another embodiment, the epoxy resin is the reaction product of a polyepoxide and a compound containing more than one isocyanate moiety or a polyisocyanate. Preferably, the epoxy resin produced in such a reaction is an epoxy-terminated polyoxazolidone. Preferably, the epoxy resin, Component (a), contains at least one oxazol idone-modified epoxy resin.

In one embodiment, the curing agent (also referred to as a hardener or a crosslinker), Component (b), utilized in the composition of the present invention includes at least one hardener compound with a phenolic hydroxyl functionality, a hardener compound capable of generating a phenolic hydroxyl functionality, or a mixture thereof. Preferably the curing agent is a compound or a mixture of compounds with phenolic hydroxyl functionalities.

Examples of compounds with a phenolic hydroxyl functionality (the phenolic curing agent) include compounds having an average of one or more phenolic groups per molecule. Suitable phenol curing agents include dihydroxy phenols, biphenols, bisphenols, halogenated biphenols, halogenated bisphenols, alkylated biphenols, alkylated bisphenols, trisphenols, phenol-aldehyde resins, phenol-aldehyde novolac resins, halogenated phenol-aldehyde novolac resins, substituted phenol-aldehyde novolac resins, phenol-hydrocarbon resins, substituted phenol-hydrocarbon resins, phenol-hydroxybenzaldehyde resins, alkylated phenol-hydroxybenzaldehyde resins, hydrocarbon-phenol resins, hydrocarbon-halogenated phenol resins, hydrocarbon-alkylated phenol resins, or combinations thereof. Preferably, the phenolic curing agent includes substituted or unsubstituted phenols, biphenols, bisphenols, novolacs or combinations thereof.

The curing agent of the present invention may be selected from, for example, phenol novolac, bisphenol A novolac, bisphenol A, tetrabromobisphenol A and mixtures thereof.

The curing agent may also include any of the multi-functional phenolic cross-linkers described in U.S. Pat. No. 6,645,631, Column 4, lines 57-67 to Column 6 lines 1-57.

In one embodiment, the curing agent contains an halogenated flame retardant. Preferably the halogenated flame retardant is a brominated flame retardant. More preferably, the brominated flame retardant is a brominated phenolic compound, such as tetrabromobisphenol A or derivatives.

Examples of curing agents capable of generating phenolic hydroxyl functionalities are benzoxazines and polybenzoxazines. By “generating” herein it is meant that upon heating the curing agent compound, the curing agent compound transforms into another compound having phenolic hydroxyl functionalities, which acts as a curing agent. Examples of Component (b) curing agents may also include compounds which form a phenolic crosslinking agent upon heating, for example, species obtained from heating bezoxazines as described in U.S. Pat. No. 6,645,631. Examples of such components also include benzoxazine of phenolphthalein, benzoxazine of bisphenol-A, benzoxazine of bisphenol-F, benzoxazine of phenol novolac. Mixtures of such components described above may also be used.

In another embodiment, one or several co-curing agents that do not contain phenolic hydroxyl functionality or capable of generating phenolic hydroxyl functionality are present in the composition. Co-curing agents useful in this invention are those compounds known to the skilled in the art to react with polyepoxides or advanced epoxy resins to form hardener final products. Such co-curing agents include, but are not limited to, amino-containing compounds, such as amines and dicyandiamide, and carboxylic acids and carboxylic anhydrides, such as styrene-maleic anhydride polymer. Preferably the molar ratio of curing agent to co-curing agent (the molar ratio is calculated based on the active groups capable of reacting with epoxides) is between 100:0 and 50:50, preferably between 100:0 and 60:40, more preferably between 100:0 and 70:30, and even more preferably between 100:0 and 80:20. Preferably the weight ratio of curing agent to co-curing agent is between 100:0 and 50:50, more preferably between 100:0 and 60:40, even more preferably between 100:0 and 70:30, and most preferably between 100:0 and 80:20.

The ratio of curing agent to epoxy resin is preferably suitable to provide a fully cured resin. The amount of curing agent which may be present may vary depending upon the particular curing agent used (due to the cure chemistry and curing agent equivalent weight) as is known in the art. In one embodiment the molar ratio between the epoxy groups of the epoxy resin, Component (a), and the reactive hydrogen groups of the hardener, Component (b), is between 1:2 and 2:1, preferably between 1.5:1 and 1:1.5, and more preferably between 1.2:1 and 1:1.2. If a co-curing agent is used in combination with the phenolic curing agent, then the molar ratios described above should be based on the combination of curing agents.

The curing catalyst of the present invention, Component (c), (also referred to as a curing accelerator) used in the epoxy resin composition of the present invention include nitrogen-containing compounds which catalyze the reaction of the epoxy resin with the curing agent. The nitrogen-containing catalyst compound of the present invention acts with the curing agent to form an infusible reaction product between the curing agent and the epoxy resin in a final article of manufacture such as a structural composite or laminate. By an infusible reaction product, it is meant that the epoxy resin has essentially completely cured, which for example may be at a time when there is little or no change between two consecutive T_{g} measurements (ΔT_{g}).

In one embodiment, the nitrogen-containing compound is a heterocyclic nitrogen compound, an amine or an ammonium compound. Preferably, the nitrogen-containing catalyst compound is an imidazole, derivatives of imidasole, or mixtures thereof. Examples of suitable imidazoles defined by the present invention include 2-methylimidazole, 2-phenyl imidazole, 2-ethyl-4-methyl imidazole, and combinations thereof. Examples of suitable catalyst compounds also include those compounds listed in European Patent Specification EP 0 954 553 B1.

The nitrogen-containing catalyst compounds of the present invention may be used alone, in combination with each other, or in combination with other accelerators or curing catalyst compounds known in the art. Other known general classes of catalyst compounds include, but are not limited to phosphine compounds, phosphonium salts, imidazoles, imidazolium salts, amines, ammonium salts, and diazabicyclo compounds as well as their tetraphenylborates salts, phenol salts and phenol novolac salts. Examples of suitable catalyst compounds to be used in combination with the nitrogen-containing catalyst compound of the present invention also include those compounds listed in U.S. Pat. No. 6,255,365.

The amount of catalyst utilized in the epoxy resin composition of the present invention is an amount effective to catalyze the reaction of the epoxy resin with the curing agent. As is known in the art, the amount of catalyst to be utilized depends upon the components utilized in the composition, the processing requirements, and the performance targets of the articles to be manufactured. In one embodiment, the amount of curing accelerators used is preferably from 0.001 percent to less than 10 percent by weight to the epoxy resin (a) (based on solids), more preferably from 0.01 percent to 5 percent by weight, even more preferably from 0.02 percent to 2 percent by weight, and even most preferably from 0.04 percent to 1 percent by weight. The amount of curing accelerators can be adjusted to achieve suitable reactivity characterized by the gel time at 170° C. In general, the stroke cure gel time of the resin at 170° C. is maintained between 90 second (s) and 600 s, preferably between 120 s and 480 s, and more preferably between 180 s and 420 s.

The entire catalyst system, Component (c), or part of the catalyst system can be conveniently incorporated into the hardener Component (b).

The catalyst adjuvant component of the present invention, Component (d), used in the epoxy resin composition of the present invention, is used to take the place of or act as a substitute component for a portion of the concentration of catalyst so as to reduce the total amount of catalyst used in the epoxy resin composition. The catalyst adjuvant is a compound different from the catalyst and does not contain a nitrogen atom.

Preferably, the catalyst adjuvant is a compound capable of reducing the concentration of the nitrogen-containing catalyst in an epoxy-containing varnish containing at least a phenolic hardener. The catalyst adjuvant is preferably capable of reacting with epoxide groups. The catalyst adjuvant is preferably a compound containing carboxylic acid or anhydride groups, or combination thereof. The preferred compounds contain at least one cyclic carboxylic anhydride group. In one embodiment, the catalyst adjuvant is trimellitic anhydride or an oligomer of trimellitic anhydride and derivatives thereof. Oligomers of trimellitic anhydride can be prepared, for example, by reacting the carboxylic acid group of trimellitic anhydride with a polyol. Examples of anhydride such as those described in U.S. Pat. No. 6,613,839. The catalyst adjuvant is used to reduce the concentration of the nitrogen-containing catalyst, such as imidazole, while maintaining similar varnish gel time and controlling other varnish, prepreg, and laminate properties (for example Tg). It is noteworthy that the use of a compound containing carboxylic acid or anhydride groups also surprisingly improves the varnish processing window. The viscosity build-up during advancement to prepare prepreg is smoother than for similar systems that do not contain such a compound.

The catalyst adjuvant may be liquid or solid at ambient temperature, and preferably soluble in the varnish system composition at ambient temperature. In one embodiment, the preferred catalyst adjuvant is liquid at processing temperature but it does not undergo extensive evaporation when subjected to processing temperature. If the catalyst adjuvant is not a liquid at processing temperature, it is at least preferred that the adjuvant be homogeneously dissolved in the composition. Preferably, the adjuvant is liquid at 180° C. with a viscosity below 100 Pa·s, preferably below 10 Pa·s, more preferably below 1 Pa·s, and even more preferably below 0.1 Pa·s. Highly viscous anhydride compounds are not suitable for the application because they generate rough prepreg. The rate of evaporation of the catalyst adjuvant in air is preferably less than 10 wt percent/min at 180° C., more preferably less than 5 wt percent/min, and even more preferably less than 1 wt percent/min. Highly volatile catalyst adjuvants may not be suitable because they tend to evaporate quickly in the treater during B-stage.

The catalyst adjuvant is present in the epoxy resin composition in the range of from 0.01 percent to 20 percent, by weight based on solids, preferably between 0.1 percent and 10 percent, more preferably between 0.5 percent and 5 percent, and even more preferably between 0.8 percent and 3 percent. Too high concentration of the catalyst adjuvant in the composition of the present invention leads to a narrow processing window and often the resulting laminates made from such a composition have low glass transition temperature, and low adhesion to copper foil; and are brittle.

The adjuvant is advantageously used with brominated, oxazolidone-modified epoxy resins. Such epoxy resins often show lower thermal stability when compared to non-brominated or to non-oxazolidone-modified resins. The present invention is very suitable to enhance the thermal stability of such oxazolidone-modified epoxy resins systems.

The present invention is also very suitable to enhance the thermal stability of compositions containing cure inhibitors such as boric acid.

In one embodiment the molar ratio between the epoxy groups of the epoxy resin, Component (a), and the combination of the reactive groups of the hardener, Component (b), and the catalyst adjuvant, Component (d), is between 1:2 and 2:1, preferably between 1.5:1 and 1:1.5, and more preferably between 1.2:1 and 1:1.2. The reactive groups are defined by the groups capable of reacting with the epoxy groups when exposed to the processing conditions described in the present invention.

Generally, the flame retardant compound, Component (e), used in the composition of the present invention is a halogenated compound. Preferred flame retardants are brominated flame retardants. Examples of brominated flame retardants include halogenated epoxy resins (especially brominated epoxy resins), tetrabromobisphenol A (TBBA) and its derivatives, D.E.R. 542™, D.E.R.™ 560 which are available from The Dow Chemical Company, a brominated phenol novolac and its glycidyl ether, TBBA epoxy oligomer, TBBA carbonate oligomer, brominated polystylene, polybromo phenylene oxide, hexabromo benzene, and tetrabromobisphenol-S and mixtures thereof. Optionally, the flame retardant may be incorporated, partly or as a whole, in the epoxy resin (a), the phenolic hardener (b), the compound (d), or a combination thereof. Examples of suitable additional flame retardant additives are given in a paper presented at “Flame retardants—101 Basic Dynamics—Past efforts create future opportunities”, Fire Retardants Chemicals Association, Baltimore Marriot Inner Harbour Hotel, Baltimore Md., Mar. 24-27 1996.

Optionally, the curable epoxy resin composition of the present invention may further contain other components typically used in an epoxy resin composition particularly for making prepegs and laminates; and which do not detrimentally affect the properties or performance of the composition of the present invention, or the final cured product therefrom. For example, other optional components useful in the epoxy resin composition may include toughening agents; curing inhibitors; fillers; wetting agents; colorants; flame retardants; solvents; thermoplastics; processing aids; fluorescent compound; such as tetraphenolethane (TPE) or derivatives thereof; UV blocking compounds; and other additives. The epoxy resin compositions of the present invention may also include other optional constituents such as inorganic fillers and additional flame retardants, for example antimony oxide, octabromodiphenyl oxide, decabromodiphenyl oxide, phosphoric acid and other such constituents as is known in the art including, but not limited to, dyes, pigments, surfactants, flow control agents, plasticizers.

In one embodiment, the epoxy resin composition may optionally contain a toughening agent that creates phase-separated micro-domains. Preferably, the toughening agent creates phase-separated domains or particles, which average size is lower than 5 micron, preferably lower than 2 micron, more preferably lower than 500 nm, and even more preferably lower than 100 nm. Preferably, the toughening agent is a block copolymer toughening agent, more preferably the toughening agent is a triblock toughening agent, or the toughening agent consists of pre-formed particles, preferably core-shell particles. In particular, the triblock copolymer could have polystyrene, polybutadiene, and poly(methyl methacrylate) segments or poly(methyl methacrylate) and poly(butyl acrylate) segments. Preferably, the toughening agent does not substantially reduce Tg of the cured system, that is reduction of Tg<15° C., preferably <10° C., more preferably <5° C. When present, the concentration of toughening agent is between 0.1 and 30 phr, preferably between 0.5 and 20 phr, more preferably between 1 and 10 phr, and even more preferably between 2 and 8 phr.

In the case of high Tg laminates, the use of a toughening agent may be needed to improve toughness and adhesion to copper. Block copolymers such as styrene-butadiene-methyl methacrylate (SBM) polymer are very suitable because they improve toughness without negative influence on other laminates properties, such as Tg, Td, and water uptake. Especially advantageous is a the combination of a catalyst adjuvant in an epoxy-containing varnish and a block copolymer toughening agent, such as SBM polymer, in an epoxy-containing varnish, preferably with a phenolic hardener, leads to laminates with excellent balance of properties, that is high Td, high Tg, and good toughness.

In another embodiment, the epoxy resin composition may optionally contain a fluorescent and a UV blocking compound, such as tetraphenolethane. Preferably, the fluorescent compound is tetraphenol ethane (TPE) or derivatives. Preferably, the UV blocking compound is TPE or derivatives.

In another embodiment, the composition of the present invention may contain a cure inhibitor, such as boric acid. In one embodiment, the amount of boric acid is preferably from 0.01 to 3 percent by weight to the epoxy resin (a) (based on solids), more preferably from 0.1 to 2 percent by weight, and more preferably from 0.2 to 1.5 percent by weight. In this embodiment, it is particularly useful to maintain the presence of a portion of imidazole catalyst since boric acid forms complexes with imidazoles which act as latent catalyst for the composition.

The epoxy resin composition of the present invention may also optionally contain a solvent with the other components of the composition; or any of the other components such as the epoxy resin, curing agent, and/or catalyst compound may optionally be used in combination with or separately be dissolved in a solvent. Preferably, the concentration of solids in the solvent is at least 50 percent and no more than 90 percent solids, preferably between 55 percent and 80 percent, and more preferably between 60 percent and 70 percent solids. Non-limiting examples of suitable solvents include ketones, alcohols, water, glycol ethers, aromatic hydrocarbons and mixtures thereof. Preferred solvents include acetone, methyl ethyl ketone, methyl isobutyl ketone, cyclohexanone, methylpyrrolidinone, propylene glycol monomethyl ether, propylene glycol monomethyl ether acetate, ethylene glycol monomethyl ether, methyl amyl ketone, methanol, isopropanol, toluene, xylene, dimethylformamide (DMF). A single solvent may be used, but also separate solvents may be used for one or more components. Preferred solvents for the epoxy resins and curing agents are ketones, including acetone, methylethyl ketone, and ether alcohols such as methyl, ethyl, propyl or butyl ethers of ethylene glycol, diethylene glycol, propylene glycol or dipropylene glycol, ethylene glycol monomethyl ether, or 1-methoxy-2-propanol, and the respective acetates. Preferred solvents for the catalyst of the present invention include alcohols, ketones, water, dimethylformamide (DMF), glycol ethers such as propylene glycol monomethyl ether or ethylene glycol monomethyl ether, and combinations thereof.

As an illustration of one embodiment of the present invention, typical components of the composition of the present invention include:

(a) an epoxy resin such as oligomeric and polymeric diglycidyl ether of bisphenol A, oligomeric and polymeric diglycidyl ether of tetrabromobisphenol A, oligomeric and polymeric diglycidyl ether of bisphenol A and tetrabromobisphenol A, epoxydized phenol novolac, epoxydized bisphenol A novolac, oxazolidone-containing epoxy resin, or a mixture thereof;

(b) a phenolic hardener such as phenol novolac, bisphenol A novolac, bisphenol A, tetrabromobisphenol A, monomeric and oligomeric and polymeric benzoxazine, or a mixture thereof;

(c) a nitrogen-containing catalyst such as imidazole;

(d) a catalyst adjuvant such as trimellitic anhydride and derivatives thereof; and

(e) a flame retardant additive such as TBBA and derivatives thereof.

The components of the compositions of the present invention may be mixed together in any order. Preferably, the composition of the present invention can be produced by preparing a first composition comprising the epoxy resin, and a second composition comprising the phenolic hardener. Either the first or the second composition may also comprise a curing catalyst, a catalyst adjuvant, and/or a flame retardant compound. All other components may be present in the same composition, or some may be present in the first, and some in the second. The first composition is then mixed with the second composition to produce a curable halogen-containing flame retardant epoxy resin composition.

The curable halogen-containing epoxy resin composition of the present invention can be used to make composite materials by techniques well known in the industry such as by pultrusion, moulding, encapsulation or coating. The resin compositions of the present invention, due to their thermal properties, are especially useful in the preparation of articles for high temperature continuous use applications. Examples include electrical laminates and electrical encapsulation. Other examples include molding powders, coatings, structural composite parts and gaskets.

The epoxy resin compositions described herein may be found in various forms. In particular, the various compositions described may be found in powder form, hot melt, or alternatively in solution or dispersion. In those embodiments where the various compositions are in solution or dispersion, the various components of the composition may be dissolved or dispersed in the same solvent or may be separately dissolved in a solvent or solvents suitable for that component, then the various solutions are combined and mixed. In those embodiments wherein the compositions are partially cured or advanced, the compositions of the present invention may be found in a powder form, solution form, or coated on a particular substrate.

In one embodiment, the present invention provides for a process for preparing a resin coated article. The process steps include contacting an article or a substrate with an epoxy resin composition of the present invention. Compositions of the present invention may be contacted with an article by any method known to those skilled in the art. Examples of such contacting methods include powder coating, spray coating, die coating, roll coating, resin infusion process, and contacting the article with a bath containing the composition. In a preferred embodiment the article is contacted with the composition in a varnish bath. In another embodiment, the present invention provides for articles, especially prepregs and laminates, prepared by the process of the present invention.

The present invention also provides a prepreg obtained by impregnating reinforcement with the composition of the present invention.

The present invention also provides a metal-coated foil obtained by coating a metal foil with the composition of the present invention.

The present invention also provides a laminate with enhanced properties obtained by laminating the above prepreg and/or the above metal-coated foil.

The curable epoxy resin composition of the present invention is amenable to impregnation of reinforcements, for example, glass cloth, and cures into products having both heat resistance and flame retardancy, so that the composition is suitable for the manufacture of laminates which have a well-balance of properties, are well-reliable with respect to mechanical strength and electrical insulation at high temperatures. The epoxy resin compositions of the present invention utilizing the curative of the present invention may be impregnated upon a reinforcing material to make laminates, such as electrical laminates. The reinforcing materials which may be coated with the compositions of the present invention include any material which would be used by one skilled in the art in the formation of composites, prepregs, laminates. Examples of appropriate substrates include fiber-containing materials such as woven cloth, mesh, mat, fibers, and unwoven aramid reinforcements such as those sold under the trademark THERMOUNT, available from DuPont, Wilmington, Del. Preferably, such materials are made from glass, fiberglass, quartz, paper, which may be cellulosic or synthetic, a thermoplastic resin substrate such as aramid reinforcements, polyethylene, poly(p-phenyleneterephthalamide), polyester, polytetrafluoroethylene and poly(p-phenylenebenzobisthiazole), syndiotatic polystyrene, carbon, graphite, ceramic or metal. Preferred materials include glass or fiberglass, in woven cloth or mat form.

In one embodiment, the reinforcing material is contacted with a varnish bath comprising the epoxy resin composition of the present invention dissolved and intimately admixed in a solvent or a mixture of solvents. The coating occurs under conditions such that the reinforcing material is coated with the epoxy resin composition. Thereafter the coated reinforcing materials are passed through a heated zone at a temperature sufficient to cause the solvents to evaporate, but below the temperature at which the resin composition undergoes significant cure during the residence time in the heated zone.

The reinforcing material preferably has a residence time in the bath of from 1 second to 300 seconds, more preferably from 1 second to 120 seconds, and most preferably from 1 second to 30 seconds. The temperature of such bath is preferably from 0° C. to 100° C., more preferably from 10° C. to 40° C. and most preferably from 15° C. to 30° C. The residence time of the coated reinforcing material in the heated zone is from 0.1 minute to 15 minutes, more preferably from 0.5 minute to 10 minutes, and most preferably from 1 minute to 5 minutes.

The temperature of such zone is sufficient to cause any solvents remaining to volatilize away yet not so high as to result in a complete curing of the components during the residence time. Preferable temperatures of such zone are from 80° C. to 250° C., more preferably from 100° C. to 225° C., and most preferably from 150° C. to 210° C. Preferably there is a means in the heated zone to remove the solvent, either by passing an inert gas through the oven, or drawing a slight vacuum on the oven. In many embodiments the coated materials are exposed to zones of increasing temperature. The first zones are designed to cause the solvent to volatilize so it can be removed. The later zones are designed to result in partial cure of the epoxy resin component (B-staging).

One or more sheets of prepreg are preferably processed into laminates optionally with one or more sheets of electrically-conductive material such as copper. In such further processing, one or more segments or parts of the coated reinforcing material are brought in contact with one another and/or the conductive material. Thereafter, the contacted parts are exposed to elevated pressures and temperatures sufficient to cause the epoxy resin to cure wherein the resin on adjacent parts react to form a continuous epoxy resin matrix between and the reinforcing material. Before being cured the parts may be cut and stacked or folded and stacked into a part of desired shape and thickness. The pressures used can be anywhere from 1 psi to 1000 psi with from 10 psi to 800 psi being preferred. The temperature used to cure the resin in the parts or laminates, depends upon the particular residence time, pressure used, and resin used. Preferred temperatures which may be used are between 100° C. and 250° C., more preferably between 120° C. and 220° C., and most preferably between 170° C. and 200° C. The residence times are preferably from 10 minutes to 120 minutes, and more preferably from 20 minutes to 90 minutes.

In one embodiment, the process is a continuous process where the reinforcing material is taken from the oven and appropriately arranged into the desired shape and thickness and pressed at very high temperatures for short times. In particular such high temperatures are from 180° C. to 250° C., more preferably 190° C. to 210° C., at times of 1 minute to 10 minutes and from 2 minutes to 5 minutes. Such high speed pressing allows for the more efficient utilization of processing equipment. In such embodiments the preferred reinforcing material is a glass web or woven cloth.

In some embodiments it is desirable to subject the laminate or final product to a post cure outside of the press. This step is designed to complete the curing reaction. The post cure is usually performed at from 130° C. to 220° C. for a time period of from 20 minutes to 200 minutes. This post cure step may be performed in a vacuum to remove any components which may volatilize.

The laminate prepared utilizing the composition in accordance with the present invention shows excellent balance of properties, that is a well-balanced combination of superior glass transition temperature (Tg), decomposition temperature (Td), time to delamination at 288° C. (T288), adhesion to copper foil (copper peel strength), and flame retardancy (flame retardancy ranking at least UL94).

The laminates prepared from the curable epoxy resin composition of the present invention exhibit enhanced thermal properties when compared to laminates utilizing prior art compositions, for example those containing accelerators, such as for example imidazoles without a catalyst adjuvant. In another embodiment, laminates prepared utilizing the catalyst and catalyst adjuvant of the present invention exhibit a well-balanced properties, such as delamination time, delamination temperature, and glass transition temperature (Tg).

The Tg is maintained in ° C., measured by differential scanning calorimetry at a heating rate of 20° C./min, of at least 90 percent, preferably of at least 95 percent, and even more preferably of at least 98 percent of that for comparable systems prepared utilizing imidazole accelerators. As utilized herein, Tg refers to the glass transition temperature of the thermosettable resin composition in its current cure state. As the prepreg is exposed to heat, the resin undergoes further cure and its Tg increases, requiring a corresponding increase in the curing temperature to which the prepreg is exposed. The ultimate, or maximum, Tg of the resin is the point at which essentially complete chemical reaction has been achieved. “Essentially complete” reaction of the resin has been achieved when no further reaction exotherm is observed by differential scanning calorimetry (DSC) upon heating of the resin.

The time to delamination of laminates prepared using the composition of the present invention as measured with a thermomechanical analyzer at a heating rate of 10° C./min to 288° C. (T288) increases by at least 5 percent, preferably 10 percent, more preferably at least 20 percent, even more preferably at least 50 percent, and most preferably at least 100 percent relative to the delamination time when compared to laminates manufactured utilizing imidazole accelerators above without a catalyst adjuvant.

In addition, the laminates prepared from the compositions of the present invention also show measurable improvement in the thermal properties of the decomposition temperature (Td) at which 5 percent of the sample weight is lost upon heating. In another embodiment the decomposition temperature Td of laminates of the present invention is increased by at least 2° C., preferably at least 4° C., even more preferably at least 8° C. when compared to laminates manufactured utilizing imidazole accelerators.

In addition to enhanced thermal properties, the non-thermal properties of the laminates prepared from the compositions of the present invention, such as water absorption, a copper peel strength, dielectric constant, and dissipation factor are comparable with those of prior art formulations utilizing known accelerators.

Preferably the epoxy resin compositions of the present invention, after curing, give a cured laminate product with the following excellent balance of properties: superior glass transition temperature (Tg>130° C., preferably Tg>150° C., more preferably Tg>170° C.), decomposition temperature (Td>320° C., preferably Td>330° C., more preferably Td>340° C., even more preferably Td>350° C.), time to delamination at 288° C. (T288>1 min, preferably >5 min, more preferably >10 min, even more preferably >15 min), adhesion to copper foil (copper peel strength>10 N/cm, preferably >12 N/cm, more preferably >16 N/cm), flame retardancy (flame retardancy ranking at least UL94 V-1, preferably UL94 V-0).

Preferably the composition of the present invention also improves the varnish processing window. The viscosity build-up during advancement to prepare prepreg is smoother than for similar systems that do not contain such a composition.

### EXAMPLES

In order to provide a better understanding of the present invention including representative advantages thereof, the following Examples are offered. The following Examples are set forth to illustrate various embodiments of the present invention; and are not intended to limit the scope of the present invention. Unless otherwise stated all parts and percentages in the Examples are by weight.

Various terms, abbreviations and designations for raw materials used in the following Examples are explained as follows:

EEW stands for epoxy equivalent weight (on solids).

HEW stands for phenolic hydroxyl equivalent weight (on solids).

Percent Br stands for bromine content (by weight, on solids).

Epoxy Resin Solution A is a solution of a blend of epoxy resins containing oxazolidone-modified epoxy resin and a mixture of brominated and non-brominated epoxy resins, EEW=291, percent Br=18.9 percent, 80 percent solids in a mixture of acetone, DOWANOL™ PMA and methanol.

Epoxy Resin Solution B is a solution of a blend of epoxy resins containing oxazolidone-modified epoxy resin and a mixture of brominated and non-brominated epoxy resins, EEW=285, percent Br=19.0 percent, 76 percent solids in a mixture of acetone, DOWANOL™ PM, DOWANOL PMA and methanol.

Hardener Resin Solution C is a phenolic hardener solution, HEW=107, 50 percent solids in a mixture of MEAK and DOWANOL PMA.

Epoxy Resin Solution D is a solution of a blend of epoxy resins containing oxazolidone-modified epoxy resin and a mixture of brominated and non-brominated epoxy resins, EEW=303, percent Br=18.2 percent, 76 percent solids in a mixture of acetone, DOWANOL PM, DOWANOL PMA and methanol.

Epoxy Resin Solution E is a solution of a blend of brominated and non-brominated epoxy resins, EEW=274, percent Br=9.9 percent, 80 percent solids in a mixture of acetone and MEK.

Epoxy Resin Solution F is a solution of a blend of epoxy resins containing oxazolidone-modified epoxy resin and a mixture of brominated and non-brominated epoxy resins, EEW=265, percent Br=11 percent, 80 percent solids in a mixture of acetone, DOWANOL PM, and methanol, commercially.

Hardener Resin Solution G is a phenolic hardener solution, 50 percent solids in DOWANOL PMA, HEW=105.

Hardener Resin Solution H is a brominated phenolic hardener solution, 60 percent solids in a mixture of DOWANOL™ PMA and acetone, HEW=128, percent Br=17-7 percent.

Hardener Resin Solution I is a phenolic hardener solution, 50 percent solids in a mixture of DOWANOL PMA and MEK, HEW=107.

TMA stands for trimellitic anhydride.

TMA-C stands for trimellitic anhydride derivative of the following formula:

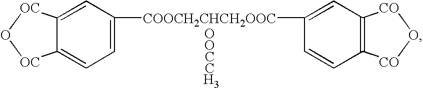

commercially available from Shin Nihon Rika.

NDA stands for 5-norbornene-2,3-dicarboxylic anhydride.

2-MI stands for 2-methyl imidazole.

DOWANOL PM is a propylene glycol methyl ether, commercially available from The Dow Chemical Company.

DOWANOL PMA is a propylene glycol methyl ether acetate, commercially available from The Dow Chemical Company.

MEK stands for methyl ethyl ketone.

The various standard test methods and procedures used in the Examples to measure certain properties are as follows:

| IPC Test Method | Property Measured |
|---|---|
| IPC-TM-650-2.3.10B | Flammability of laminate [UL94] |
| IPC-TM-650-2.3.16.1C | Resin content of prepreg, by treated weight [resin content] |
| IPC-TM-650-2.3.17D | Resin flow percent of prepreg [resin flow] |
| IPC-TM-650-2.3.18A | Gel time, prepreg materials [prepreg gel time] |
| | Note: Similar method was used to determine varnish stroke |
| | cure gel time |
| IPC-TM-650-2.3.40 | Thermal stability [Td] |
| | Note: Td was determined with a heating ramp of 10° C./min; |
| | Experimental error is +/−1° C. |
| IPC-TM-650-2.4.8C | Peel strength of metallic clad laminates [copper peel |
| | strength (CPS)] |
| IPC-TM-650-2.4.24C | Glass transition temperature and z-axis Thermal expansion |
| | by Thermal Mechanical Analysis (TMA) [Coefficient of |
| | Thermal Expansion (CTE)] |
| IPC-TM-650-2.4.24.1 | Time to delamination (TMA Method) [T260, T288, T300] |
| IPC-TM-650-2.4.25C | Glass transition temperature and cure factor by DSC [Tg] |
| | Note: Tg was determined on films with a heating ramp of |
| | 10° C./min and on laminates with a heating ramp of |
| | 20° C./min; Experimental error is +/−1° C. |
| IPC-TM-650-2.5.5.9 | Permittivity and loss tangent, parallel plate, 1 MHz to 1.5 GHz |
| | [Dk/Df measurements] |
| IPC-TM-650-2.6.16 | Pressure vessel method for glass epoxy laminate integrity |
| | [high pressure cooker test (HPCT)] |
| | Note: Laminates coupons were conditioned in the pressure |
| | vessel in a moisture-saturated atmosphere at 121° C. for 2 h |

Cure schedule for film curing on heating plate: 10 minutes@170° C. followed by 90 minutes@190° C.

### Examples

### General Procedures

Epoxy resin varnish formulations were prepared by dissolving the individual resin, curing agent, and accelerator catalyst components in suitable solvents at room temperature and mixing the solutions. Prepregs were prepared by coating the epoxy resin varnish on style 7628 glass cloth (Porcher 731 finish) and drying in a horizontal laboratory treater oven at 173° C. for 2-5 minutes to evaporate the solvents and advance the reacting epoxy/curing agent mixture to a non-tacky B-stage. Laminates were prepared using 1-8 prepreg plies sandwiched between sheets of copper foil (Circuit Foil TW 35 μm) and pressing at 190° C. for 90 minutes. Pressure was adjusted to control a laminate resin content equal to 43-45 percent.

Several different resin and curing agent systems were tested to verify the performance increase provided by the present invention presented here and these systems are summarized by the following Examples.

### Example 1

| | Example 1A | | |
|---|---|---|---|
| Varnish Composition Raw | Comparative | | |
| Materials | Example | Example 1B | Example 1C |
| Epoxy Resin Solution A | 27.9 g | 27.9 g | 27.9 g |
| Hardener Resin Solution C | 15.4 g | 14.4 g | 13.4 g |
| TMA | 0 g | 0.45 g | 0.89 g |
| 2-MI [20 percent solids in | 0.52 g | 0.45 g | 0.37 g |
| DOWANOL PM] | | | |

MEK was added to the above varnish compositions to adjust the solids content to 65 percent.

Films were prepared from the varnish compositions above and tested. The results of testing the films were as follows:

| | Example 1A | | |
|---|---|---|---|
| | Comparative | | |
| Test Results | Example | Example 1B | Example 1C |
| Varnish gel time (s) | 235 | 239 | 243 |
| Film Tg (° C.) | 139 | 147 | 154 |
| Film Td @10 percent wt loss | 324 | 329 | 333 |
| (° C.) | | | |

The films prepared from Example 1 B and Example 1 C showed improved thermal stability and higher glass transition temperature when compared to the film prepared from Comparative Example 1 A, while all varnishes displayed similar gel time. The higher the concentration of TMA was, the better the thermal stability.

### Example 2

| | Example 2A | | |
|---|---|---|---|
| Varnish | Comparative | | |
| Composition Raw Materials | Example | Example 2B | Example 2C |
| Epoxy Resin Solution B | 29.3 g | 29.3 g | 29.3 g |
| Hardener Resin solution C | 14.9 g | 14.2 g | 13.5 g |
| TMA-C | 0 g | 0.6 g | 1.5 g |
| 2-MI [20 percent solids in | 0.45 g | 0.37 g | 0.15 g |
| DOWANOL PM] | | | |

MEK was added to the above varnish compositions to adjust the solids content to 65 percent.

Films were prepared from the varnish compositions above and tested. The results of testing the films were as follows:

| | Example 2A | | |
|---|---|---|---|
| | Comparative | | |
| Test Results | Example | Example 2B | Example 2C |
| Varnish gel time (s) | 293 | 296 | 259 |
| Film Tg (° C.) | 172 | 172 | 158 |
| Film Td @10 percent wt loss | 320 | 325 | 342 |
| (° C.) | | | |

The films prepared from Example 2B and Example 2C showed improved thermal stability when compared to the film prepared from Comparative Example 2A, while all varnishes displayed similar gel time. The higher the concentration of TMA was, the better the thermal stability.

### Example 3

| | Example 3A | | |
|---|---|---|---|
| Varnish | Comparative | | |
| Composition Raw Materials | Example | Example 3B | Example 3C |
| Epoxy Resin Solution B | 29.0 g | 29.0 g | 29.0 g |
| Hardener Resin Solution G | 15.6 g | 14.8 g | 14.7 g |
| TMA | 0 g | 0.36 g | 0 g |
| NDA | 0 g | 0 g | 0.60 g |
| 2-MI [20 percent solids in | 0.45 g | 0.30 g | 0.30 g |
| DOWANOL PM] | | | |

DOWANOL™ PM was added to the above varnish compositions to adjust the solids content to 65 percent.

Films were prepared from the varnish compositions above and tested. The results of testing the films were as follows:

| | Example 3A | | |
|---|---|---|---|
| | Comparative | | |
| Test Results | Example | Example 3B | Example 3C |
| Varnish gel time (s) | 246 | 327 | 276 |
| Film Tg (° C.) | 181 | 179 | 181 |
| Film Td @10 percent wt loss | 331 | 339 | 340 |
| (° C.) | | | |

The films prepared from B and C showed improved thermal stability when compared to the film prepared from Comparative A, while maintaining similar glass transition temperature.

### Example 4

| | Example 4A | |
|---|---|---|
| | Comparative | |
| Varnish Composition Raw Materials | Example | Example 4B |
| Epoxy Resin Solution A | 2993.9 g | 0 g |
| Epoxy Resin Solution B | 0 g | 3081.0 g |
| Hardener Resin Solution C | 1897.6 g | 1590.4 g |
| TMA | 0 g | 47.5 g |
| 2-MI [20 percent solids in | 79.1 g | 28.5 g |
| DOWANOL PM] | | |

MEK was added to the above varnish composition to adjust the solids content to 65 percent.

The varnishes described above in Example 4 were used to impregnate 7628 type E-glass cloth, which was then passed through a lab treater to obtain a prepreg. Prepreg resin content was controlled around 44 percent. The processing window of the formulations was determined by comparing the prepreg minimum melt viscosity as a function of the prepreg gel time. It is known in the art that the smoother the transition is, the better the processing window.

### Example 5A

### Comparative Example

Properties of Prepeg prepared from Resin of Example 4A - Comparative
Example

| | | | | |
|---|---|---|---|---|
| Gel time | 80 | 57 | 54 | 42 |
| @170° C. (s) | | | | |
| Minimum melt viscosity | 10 | 21 | 32 | 97 |
| @140° C. (Pa s) | | | | |

### Example 5B

Properties of Prepeg prepared from Resin of Example 4B

| | | | | |
|---|---|---|---|---|
| Gel time | 154 | 106 | 94 | 42 |
| @170° C. (s) | | | | |
| Minimum melt viscosity | 27 | 38 | 59 | 123 |
| @140° C. (Pa s) | | | | |

The prepreg (Example 5B) produced with the resin of Example 4B showed improved processing window when compared with the prepeg (Example 5A) produced with the resin of Comparative Example 4A. Indeed for a given gel time, the minimum melt viscosity was higher and the variation of minimum melt viscosity as a function of prepreg gel time was smoother, as seen in FIG. 1. Experimental data were best fitted with a Power equation. The accuracy of the fits was good, with coefficients of determination R²>0.95. It is known in the industry than prepreg minimum melt viscosity measured at 140° C. must be kept between 30 Pa·s and 200 Pa·s, preferably between 50 Pa·s and 150 Pa·s, to ensure optimal control of wetting and flow during pressing operation. The width of processing window was defined between the viscosity limits, that is between 30 Pa·s and 200 Pa·s, and preferably between 50 Pa·s and 150 Pa·s. The wider the processing window is, the more process friendly the composition. The width of processing window of Example 4B shows over 400 percent increase when compared with Comparative Example 4A.

| | | Example 5B |
|---|---|---|
| | Comparative Example 5A | prepreg |
| | prepreg processing | processing |
| | windows | windows |
| from 30 Pa · s to 200 Pa · s | 23 | 116 |
| from 50 Pa · s to 150 Pa · s | 13 | 57 |

### Example 6

### Production of Laminate

Copper clad laminates were produced stacking 8 plies of the above prepreg produced in Example 5 between 2 sheets of standard 35 μm copper foil. The construction was pressed at 20 N/cm² at 190° C., for 1 h30. The resin content of the laminates was 43 percent

| | Example 6A - | |
|---|---|---|
| | Comparative | |
| | Example | |
| | Laminate Prepared | |
| | from prepreg of | Example 6B |
| | Example 5A | Laminate Prepared |
| | Comparative | from prepreg of |
| Laminate Properties | Example | Example 5B |
| Tg (DSC, mid point, | 176 | 178 |
| 20° C./min), ° C. | | |
| CTE <Tg/>Tg (TMA), ppm/K | 91/299 | 91/250 |
| Average CTE (50-260° C.), | 3.4 | 3.4 |
| percent | | |
| T260 (TMA), min | 34 | >60 |
| T288 (TMA), min | 5 | 12 |
| Td (TGA, 5 percent wt loss, | 326 | 340 |
| 10° C./min), ° C. | | |
| UL 94, rating | V-0 | V-0 |
| Water uptake (High Pressure | 0.38 percent | 0.35 percent |
| Cooker, 2 h, 121° C.), wt | | |
| percent | | |
| High Pressure Cooker 2 h + | 100 percent | 100 percent |
| 2 min dip @288° C., | | |
| percent pass visual | | |
| Dk/Df @1 MHz | 4.63/0.016 | 4.42/0.012 |
| Dk/Df @1 MHz | 4.22/0.012 | 4.16/0.011 |
| Copper Peel Strength, 35 μm | 19.9 | 18.6 |
| standard copper, N/cm² | | |
| Toughness (punching test)* | pass | pass |

*“pass” means no delamination after punching test (impact test)

The laminate described in Example 6B showed an outstanding balance of properties, that is superior thermal stability, Tg, flame retardancy, humidity resistance, adhesion to copper, and toughness. The combination of high Tg, high Td, high copper peel strength, and high toughness is especially noteworthy. When compared to the Comparative Example 6A, Example 6B, displayed improved thermal stability, while maintaining or improving other properties.

### Example 7

| | Example 7A | Example |
|---|---|---|
| Varnish Composition Raw Materials | Comparative Example | 7B |
| Epoxy Resin Solution D | 132.6 g | 132.6 g |
| Hardener Resin Solution I | 68.5 g | 68.5 g |
| TMA | 0 g | 2.0 g |
| 2-MI [20 percent solids in | 1.80 g | 1.25 g |
| DOWANOL PM] | | |

MEK was added to the above varnish composition to adjust the solids content to 65 percent.

### Example 8

The varnishes described in Example 7 were used to impregnate 7628 type glass cloth, which was then partly cured in a lab oven to obtain prepreg sheets. The prepreg resin content was 43 percent. A sheet of prepreg was then fully cured in a ventilated oven at 170° C. for 1 hour and 30 minutes.

| | Example 8A | |
|---|---|---|
| Test Results | Comparative Example | Example 8B |
| Varnish gel time (s) | 316 | 298 |
| Sheet Tg (° C.) | 171 | 171 |
| Sheet Td @5 percent wt loss (° C.) | 330 | 338 |

The sheet Example 8B prepared from Example 7B showed improved thermal stability when compared to the sheet Example 8A prepared from Comparative Example 7A, while varnishes displayed similar gel time and maintaining high Tg of the fully cured sheet.

### Example 9

| | Example 9A | Example |
|---|---|---|
| Varnish Composition Raw Materials | Comparative Example | 9B |
| Epoxy Resin Solution F | 125 g | 125 g |
| Hardener Resin Solution H | 79.8 g | 75.2 g |
| TMA | 0 g | 2.2 g |
| 2-MI [20 percent solids in | 1.1 g | 1.0 g |
| DOWANOL PM] | | |

MEK was added to the above varnish composition to adjust the solids content to 65 percent.

### Example 10

The varnishes described in Example 9 were used to impregnate 7628 type glass cloth, which was then partly cured in a lab oven to obtain prepreg sheets. The prepreg resin content was 43 percent. A sheet of prepreg was then fully cured in a ventilated oven at 170° C. for 1 hour and 30 minutes.

| | Example 10A | Example |
|---|---|---|
| Test Results | Comparative Example | 10B |
| Varnish gel time (s) | 295 | 263 |
| Sheet Tg (° C.) | 154 | 153 |
| Sheet Td @5 percent wt loss (° C.) | 332 | 338 |

The sheet Example 10B prepared from Example 9B showed improved thermal stability when compared to the sheet Example 10A prepared from Comparative Example 9A, while varnishes displayed similar gel time and maintaining Tg of the fully cured sheet.

### Example 11

| | Example 11A | Example |
|---|---|---|
| Varnish Composition Raw Materials | Comparative Example | 11B |
| Epoxy Resin Solution E | 125 g | 125 g |
| Hardener Resin Solution H | 77.8 g | 73.2 g |
| TMA | 0 g | 2.1 g |
| 2-MI [20 percent solids in | 1.2 g | 0.9 g |
| DOWANOL PM] | | |

MEK was added to the above varnish composition to adjust the solids content to 65 percent.

### Example 12

The varnishes described in Example 11 were used to impregnate 7628 type glass cloth, which was then partly cured in a lab oven to obtain prepreg sheets. The prepreg resin content was 43 percent. A sheet of prepreg was then fully cured in a ventilated oven at 170° C. for 1 hour and 30 minutes.

| | Example 12A | Example |
|---|---|---|
| Test Results | Comparative Example | 12B |
| Varnish gel time (s) | 294 | 291 |
| Sheet Tg (° C.) | 150 | 146 |
| Sheet Td @5 percent wt loss (° C.) | 346 | 358 |

The sheet Example 12B prepared from Example 11B showed much improved thermal stability when compared to the sheet Example 12A prepared from Comparative Example 11 A, while displaying similar varnishes gel time.

While the present invention has been described and illustrated by reference to particular embodiments, those of ordinary skill in the art will appreciate that the present invention lends itself to variations not necessarily illustrated herein. For this reason, then, reference should be made solely to the appended claims for purposes of determining the true scope of the present invention.

What is claimed is:

1. A curable halogen-containing epoxy resin composition comprising:
(a) at least one epoxy resin;
(b) at least one hardener; wherein the hardener is a compound containing a phenolic hydroxyl functionality or a compound capable of generating a phenolic hydroxyl functionality upon heating;
(c) a catalytic amount of a nitrogen-containing catalyst; and
(d) a non-nitrogen containing catalyst adjuvant compound capable of reducing the concentration of the nitrogen-containing catalyst;
wherein at least one or more of the above components (a)-(d) is halogenated or contains halogen; or if none of the above components are halogenated wherein the resin composition includes (e) a halogenated or halogen-containing flame retardant compound; characterized in that the stroke cure gel time of the resin composition is maintained from 90 seconds to 600 seconds when measured at 170° C.; and such that a resultant cured product formed by curing the curable epoxy resin composition contains the following well-balanced properties:
(1) a Tg of greater than 130° C.;
(2) a Td of greater than 320° C.;
(3) a T288 of greater than 1 min;
(4) an adhesion to copper of greater than 10 N/cm; and
(5) a UL94 flame retardancy ranking at least V-1.

2. The epoxy resin composition of claim 1 wherein the epoxy resin is a halogen-containing epoxy resin.

3. The epoxy resin composition of claim 2 wherein the halogen-containing epoxy resin is a brominated epoxy resin.

4. The epoxy resin composition of claim 2 wherein the halogen-containing epoxy resin is diglycidyl ether of tetrabromobisphenol A.

5. The epoxy resin composition of claim 1 wherein the epoxy resin is an oxazolidone-modified epoxy resin.

6. The epoxy resin composition of claim 1 wherein the hardener is a compound with a phenolic hydroxyl functionality.

7. The epoxy resin composition of claim 1 wherein the hardener is a phenol or a phenol type compound, selected from the group consisting of bisphenols, halogenated bisphenols, hydrogenated bisphenols, novolac resins, polyalkylene glycols and combinations thereof.

8. The epoxy resin composition of claim 6 wherein the hardener is a brominated phenolic resin.

9. The epoxy resin composition of claim 1 wherein the hardener is a compound capable of generating a hydroxyl functionality upon heating.

10. The epoxy resin composition of claim 9 wherein the hardener is a benzoxazine or a polybenzoxazine.

11. The epoxy resin composition of claim 1 wherein the catalyst is a heterocyclic nitrogen compound, an amine, an ammonium compound, or a mixture thereof.

12. The epoxy resin composition of claim 1 wherein the catalyst is an imidazole, a derivative of imidazole, or a mixture of thereof.

13. The epoxy resin composition of claim 1 wherein the catalyst adjuvant is a carboxylic acid, a carboxylic anhydride, or a mixture thereof.

14. The epoxy resin composition of claim 1 wherein catalyst adjuvant is trimelletric anhydride, a derivative of trimelletric anhydride or mixtures thereof.

15. The epoxy resin composition of claim 1 wherein the halogenated flame retardant compound is tetrabromobisphenol A, a derivative of tetrabramobiephenol A or mixtures thereof.

16. The epoxy resin composition of claim 1 including a solvent.

17. The epoxy resin composition of claim 1 including a cure inhibitor.

18. The epoxy resin composition of claim 14 wherein the cure inhibitor is boric acid.

19. The epoxy resin composition of claim 1 wherein the amount of the hardener present in the composition is such that the halogen-containing epoxy resin to the hardener molar ratio is between 2:1.0 and 1.0:2.

20. The epoxy resin composition of claim 1 wherein the catalyst adjuvant is present in the composition between 0.01 percent and 20 percent by weight on total solids.

21. The epoxy resin composition of claim 1 wherein the catalyst adjuvant is a liquid at 180° C. with a viscosity of less than 100 Pa·s.

22. The epoxy resin composition of claim 1 wherein the catalyst adjuvant has an evaporation rate at 180° C. lower than 10 wt percent/min.

23. A fiber reinforced composite article comprising a matrix including an epoxy resin composition according to claim 1.

24. The fiber reinforced composite article of claim 20, which is a laminate or a prepreg for an electric circuit.

25. An electric circuit component having an insulating coating of the epoxy resin composition according to claim 1.

26. A process of producing a coated article, comprising coating an article with an epoxy resin composition according to claim 1, and heating the coated article to cure the epoxy resin composition.

27. A prepreg comprising:
(a) a woven fabric, and
(b) an epoxy resin composition according to claim 1.

28. A laminate comprising:
(a) a substrate including an epoxy resin composition according to claim 1; and
(b) a layer of metal disposed on at least one surface of said substrate.

29. The laminate of claim 28 wherein the substrate further comprises a reinforcement of a woven glass fabric, wherein the epoxy resin composition is impregnated on the woven glass fabric.

30. A printed circuit board (PCB) made of the laminate of claim 28.

31. A process for preparing a resin coated article, the process comprising contacting a substrate with an epoxy resin composition of claim 1.

32. The process of claim 31 wherein the substrate is a metal foil.

33. The process of claim 32 wherein the metal foil is copper.

34. The process of claim 31 wherein the epoxy resin composition further comprises one or more solvent(s).

35. The process of claim 31 wherein the epoxy resin composition is in powder, hot melt, solution or dispersion form.

36. The process of claim 31 wherein the contacting method is selected from the group consisting of powder coating, spray coating, die coating, roll coating, resin infusion and contacting the substrate with a bath comprising the epoxy resin composition.

37. The process of claim 31 wherein the substrate comprises a material selected from the group consisting of glass, fiberglass, quartz, paper, thermoplastic resin, an unwoven aramid reinforcement, carbon, graphite, ceramic, metal and combinations thereof.

38. The process of claim 31 wherein the article is a prepreg, wherein the substrate comprises a material selected from the group consisting of glass, fiberglass, quartz, paper, thermoplastic resin, an unwoven aramid reinforcement, carbon, graphite and combinations thereof; and wherein the contacting occurs in a bath comprising the epoxy resin composition and optionally one or more solvent(s).

39. The process of claim 38 wherein the substrate is glass or fiberglass in the form of a woven cloth or a mat.

40. The process of claim 31 wherein the catalyst is an imidazole or a mixture of imidazoles.

41. The process of claim 31 wherein the catalyst adjuvant is a carboxylic acid; a carboxylic anhydride, or a mixture of thereof.

42. The process of claim 31 wherein the catalyst adjuvant is trimellitic anhydride, a derivative of trimellitic anhydride or mixtures thereof.

43. The process of claim 31 wherein the catalyst adjuvant is utilized in an amount of 0.1 percent to 10 percent by weight on total solids.

44. The process of claim 31 wherein the catalyst adjuvant is a liquid at 180° C. with a viscosity of less than 10 Pa·s.

45. The process of claim 31 wherein the catalyst adjuvant is a liquid at 180° C. with an evaporation rate of less than 5 wt percent/min.

46. The process of claim 31 wherein the epoxy resin is brominated epoxy resin.

47. The process of claim 31 wherein the epoxy resin is an oxazolidone-modified epoxy resin.

48. The process of claim 31 wherein the hardener is a phenol or a phenol type compound selected from the group consisting of bisphenols, halogenated bisphenols, hydrogenated bisphenols, novolac resins, polyalkylene glycols and combinations thereof.

49. A resin coated article prepared by the process of claim 31.

50. A prepreg prepared by the process of claim 31.
